(19) United States
(12) Patent Application Publication
(10) Pub. No.: US 2026/0229445 A1
(43) Pub. Date: Aug. 6, 2026

(54) Vertically oriented implanter architecture for contactless backside substrate processing

(71) Applicant: Applied Materials, Inc., Santa Clara, CA (US)

(72) Inventors: Frank Sinclair, Hartland, ME (US); Taegon Kim, Middleton, MA (US); Joseph C. Olson, Beverly, MA (US); Sage Toko Garrett Doshay, Saratoga, CA (US)

(21) Appl. No.: 19/047,236

(22) Filed: Feb. 6, 2025

(51) Int. Cl. H01J 37/20; H01J 37/08; H01J 37/12; H01J 37/317

(52) U.S. Cl. CPC H01J 37/20; H01J 37/08; H01J 37/12; H01J 37/3171; H01J 2237/1207; H01J 2237/20207; H01J 2237/20214; H01J 2237/20228

(57) ABSTRACT

An ion implanter is disclosed. The ion implanter generates a vertically oriented ion beam that is used to impact a workpiece. The vertically oriented ion beam may be a spot beam that is directed toward the workpiece. The workpiece is mounted on a hollow workpiece holder. The hollow workpiece holder is attached to a workpiece motion system, which is capable of moving the hollow workpiece holder in at least two directions such that the entirety of the workpiece may be impacted by the stationary spot ion beam. In some embodiments, the workpiece motion system may support a plurality of workpieces.

### FIELD

Embodiments of the present disclosure relate to an implanter architecture that allows processing of the backside without contacting the front surface of the workpiece.

### BACKGROUND

The fabrication of semiconductor devices continues to become more complex. Currently, there are scenarios in which it may be desirable to process both surfaces of a workpiece, such as a silicon, silicon carbide, or GaN wafer. For example, to create certain structures, it may be beneficial to perform an ion implantation process on both surfaces of a workpiece.

One such application of backside (BS) processing is ion implantation to relieve or control wafer stress and physical deformation. Specifically, warpage of the workpiece may occur due to stressed films that are present on the workpiece. This warpage makes lithography more difficult and causes other problems. For example, EUV patterning has a small depth of focus, and workpiece warpage may be sufficient to result in incorrect critical dimensions (CDs), poorly reproduced patterned features, and/or defects due to parts of the workpiece being out of focus. Additionally, backside power delivery networks involve also patterning the backside of the workpiece for direct backside source/drain contact, and rely on excellent pattern overlay across the entire workpiece to align the BS metallization to the frontside devices. With significant wafer stress resulting in varying localized warpage across the workpiece, it may not be possible to achieve the desired alignment across the entire workpiece, resulting in decreased yield as misaligned dies will not function as designed. Selective ion implantation into films on the front or back side of the workpiece may be used to reduce wafer curvature.

Typically when both surfaces of the workpiece are to be processed, this may be achieved by processing the front surface first. However, in certain embodiments, the processing of the front surface may include the formation of three-dimensional structures, such as finFETs. Once these three-dimensional structures are created, placing the front surface against an electrostatic chuck risks damaging these structures. Similarly, if the backside of the workpiece has been processed to form structures, subsequently placing the backside against the electrostatic chuck risks damage.

Therefore, it would be beneficial if there were an implanter system that allowed one side of the workpiece, such as the backside, to be processed, without having to contact the opposite surface, which may already have been processed.

### SUMMARY

An ion implanter is disclosed. The ion implanter generates a vertically oriented ion beam that is used to impact a workpiece. The vertically oriented ion beam may be a spot beam that is directed toward the workpiece. The workpiece is mounted on a hollow workpiece holder. The hollow workpiece holder is attached to a workpiece motion system, which is capable of moving the hollow workpiece holder in at least two directions such that the entirety of the workpiece may be impacted by the stationary spot ion beam. In some embodiments, the workpiece motion system may support a plurality of workpieces.

According to one embodiment, an ion implanter is disclosed. The ion implanter comprises an ion source to generate a vertically oriented spot beam; a beam focusing component to focus the vertically oriented spot beam into a focused spot beam; a hollow workpiece holder to hold a workpiece, such that the workpiece is supported in an edge exclusion region; and a workpiece motion system to move the hollow workpiece holder in two directions through the focused spot beam. In some embodiments, the two directions are substantially perpendicular to a direction of travel of the focused spot beam. In some embodiments, the workpiece motion system is adapted to move or tilt in a third direction, which is a vertical direction. In some embodiments, the beam focusing component comprises an electrostatic Einzel lens. In some embodiments, the beam focusing component comprises a quadrupole or octupole lens. In some embodiments, the workpiece motion system comprises two linear actuators configured to move in perpendicular directions. In some embodiments, the focused spot beam has a diameter of 5 mm or less. In some embodiments, the focused spot beam travels upward and impacts a surface of the workpiece supported by the hollow workpiece holder. In some embodiments, a mechanism is used to block the focused spot beam from striking the workpiece. In certain embodiments, the mechanism comprises an electrostatic or mechanical shutter. In certain embodiments, the mechanism comprises pulsing a voltage applied to the ion source or to extraction optics disposed outside the ion source and proximate to an extraction aperture of the ion source.

According to another embodiment, an ion implanter is disclosed. The ion implanter comprises an ion source to generate a vertically oriented spot beam; a beam focusing component to focus the vertically oriented spot beam into a focused spot beam; a plurality of hollow workpiece holders, each to hold a respective workpiece, such that each workpiece is supported in an edge exclusion region; and a workpiece motion system to rotate the plurality of hollow workpiece holders and to move the plurality of hollow workpiece holders through the focused spot beam. In some embodiments, the plurality of hollow workpiece holders are each mounted on a respective spoke, and the workpiece motion system comprises a rotary actuator in communication with the spokes to rotate the plurality of hollow workpiece holders. In certain embodiments, an axis of rotation of the rotary actuator is parallel to a direction of travel of the focused spot beam. In certain embodiments, the workpiece motion system comprises a linear actuator to move the plurality of hollow workpiece holders in a direction, wherein the direction is substantially perpendicular to a direction of travel of the focused spot beam. In certain embodiments, the workpiece motion system is adapted to move or tilt in a second direction, which is a vertical direction. In some embodiments, the beam focusing component comprises an electrostatic Einzel lens, a quadrupole or octupole lens. In some embodiments, the focused spot beam has a diameter of 5 mm or less. In some embodiments, a mechanism is used to block the focused spot beam from striking the workpieces. In certain embodiments, the mechanism comprises an electrostatic or mechanical shutter or comprises pulsing a voltage applied to the ion source or to extraction optics disposed outside the ion source and proximate to an extraction aperture of the ion source.

### BRIEF DESCRIPTION OF THE FIGURES

For a better understanding of the present disclosure, reference is made to the accompanying drawings, which are incorporated herein by reference and in which:

FIG. 1 is an ion implanter that generates a vertically oriented ion beam according to one embodiment;

FIG. 2 shows a workpiece motion system according to one embodiment;

FIGS. 3A-3C show several possible motion patterns that may be created using the workpiece motion system of FIG. 2; and

FIG. 4 shows a workpiece motion system according to a second embodiment.

### DETAILED DESCRIPTION

As described above, in certain systems, it may be desirable to process the backside of a workpiece without contacting the useable region of the front surface.

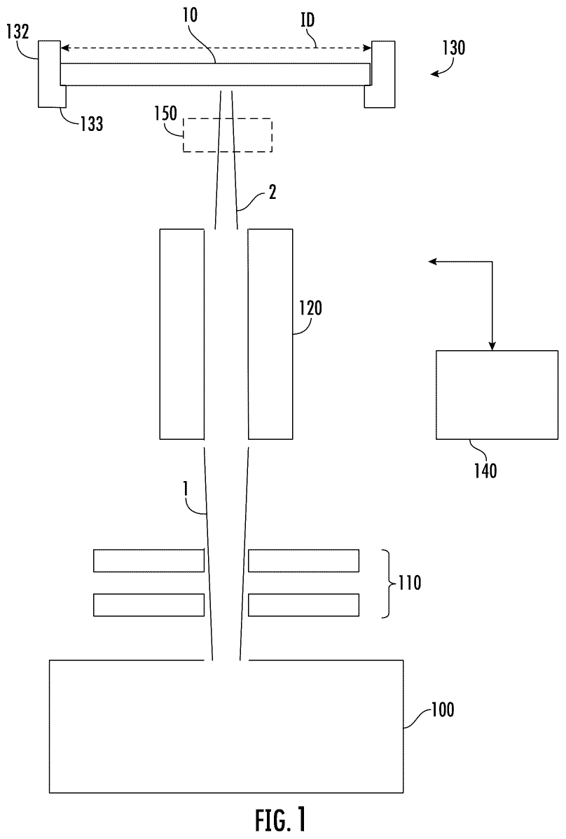

FIG. 1 shows an ion implanter system that may be used to create a vertically oriented ion beam that impacts the workpiece according to one embodiment.

The ion implanter system includes an ion source 100 comprising a plurality of chamber walls defining an ion source chamber. In certain embodiments, the ion source 100 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHz. Further, the power supplied by the RF power supply may be pulsed.

In another embodiment, a cathode is disposed within the ion source chamber. A filament is disposed behind the cathode and energized so as to emit electrons. These electrons are attracted to the cathode, which in turn emits electrons into the ion source chamber. This cathode may be referred to as an indirectly heated cathode (IHC), since the cathode is heated indirectly by the electrons emitted from the filament.

Other embodiments are also possible. For example, the plasma may be generated in a different manner, such as by a Bernas ion source, a capacitively coupled plasma (CCP) source, or a microwave or ECR (electron-cyclotron-resonance) ion source. The manner in which the plasma is generated is not limited by this disclosure.

One chamber wall, referred to as the extraction plate, includes an extraction aperture. The extraction aperture may be an opening through which the ions generated in the ion source chamber are extracted and directed toward a workpiece. The extraction aperture may be any suitable shape. In certain embodiments, the extraction aperture may be round.

Disposed outside and proximate the extraction aperture of the ion source 100 are extraction optics 110. In certain embodiments, the extraction optics 110 comprises one or more electrodes. Each electrode may be a single electrically conductive component with an aperture disposed therein. The electrodes may be a metal, such as tungsten, molybdenum or titanium. The electrodes may alternatively be made out of graphite. One or more of the electrodes may be electrically connected to ground. In certain embodiments, one or more of the electrodes may be biased using an electrode power supply. The electrode power supply may be used to bias one or more of the electrodes relative to the ion source 100 so as to attract ions through the extraction aperture. The extraction aperture and the aperture in the extraction optics are aligned such that the ions pass through both apertures. These ions form a spot beam 1. The spot beam 1 has a roughly circular cross-section. As the spot beam 1 exits the extraction optics 110, its diameter tends to increase due to various phenomenon, such as space charge. In certain embodiments, the diameter of the spot beam 1 may expand from between 6 mm and 8 mm to roughly 30 mm.

Located downstream from the extraction optics 110 are one or more beam focusing components. In one embodiment, the beam focusing component 120 may be an electrostatic Einzel lens, a quadrupole lens or an octopole lens. As the spot beam 1 passes through the beam focusing component 120, the diameter of the spot beam 1 may be reduced. In certain embodiments, the diameter of the spot beam 1 entering the beam focusing component 120 may be 30 mm, while the diameter of the focused spot beam 2 exiting the beam focusing component 120 may be 5 mm or less. The focused spot beam 2 may have a circular or nearly circular cross-section. This focused spot beam 2 is vertically oriented. In this disclosure, “vertically oriented” indicates that the focused spot beam 2 travels along a path that is within 10° of being vertical.

This focused spot beam 2 is then directed toward the workpiece 10. The workpiece 10 may be disposed on a hollow workpiece holder 130. The hollow workpiece holder 130 may include sidewalls 132 that have an inner diameter (ID) that is slightly larger than the diameter of the workpiece 10. Extending radially inward from the bottom of the sidewalls 132 is a support shelf 133. The support shelf 133 may extend inward a distance of between 2 and 5 mm, which corresponds to the width of the edge exclusion region of the workpiece 10. In this way, the support shelf 133 does not contact any part of the workpiece 10 that may contain usable devices or structures. Of course, the hollow workpiece holder 130 may be formed differently. However, in all embodiments, there is no bottom surface of the hollow workpiece holder 130 so that the focused spot beam 2 may contact the entirety of the workpiece facing the ion beam (except the edge exclusion region) without interference or blockage.

In certain embodiments, the distance from the ion source 100 to the hollow workpiece holder 130 may be 1.5 meters or less. Further, in some embodiments, the beam focusing component 120 may be disposed about halfway between the extraction optics 110 and the hollow workpiece holder 130. Note that there is no mass analyzer in this ion implanter system.

Further, in certain embodiments, a shutter 150 may be disposed between the beam focusing component 120 and the hollow workpiece holder 130. This shutter 150 may be electrostatic and deflect the focused spot beam 2 from striking the workpiece 10. In other embodiments, the shutter 150 may be a mechanical component that is placed in the path of the focused spot beam 2 to block the focused spot beam 2.

In another embodiment, the focused spot beam 2 may be interrupted by pulsing the voltage applied to the extraction optics 110 or the extraction voltage applied to the ion source 100.

All of these approaches provide mechanisms to stop the focused spot beam 2 from striking the workpiece 10.

The path of ions from the ion source 100 to the workpiece 10 is substantially straight. In some embodiments, “substantially straight” denotes that the path does not deviate by more than 30 mm.

A controller 140 may be in communication with one or more of the components in the ion implanter so as to receive information from these components or send control signals to these components. For example, the controller 140 may communicate with power supplies associated with the ion source 100, the extraction optics 110, the beam focusing component 120, or the workpiece motion system 200 (to be described below). The controller 140 may include a processing unit, such as a microcontroller, a personal computer, a special purpose controller, or another suitable processing unit. The controller 140 may also include a non-transitory storage element, such as a semiconductor memory, a magnetic memory, or another suitable memory. This non-transitory storage element may contain instructions and other data that allows the controller 140 to perform the functions described herein.

The workpiece motion system to support the hollow workpiece holder 130 may be implemented in a variety of ways. In each embodiment, the workpiece motion system is designed such that hollow workpiece holder 130 is able to move so that the entirety of the workpiece 10 may be impacted by the focused spot beam 2, which remains stationary.

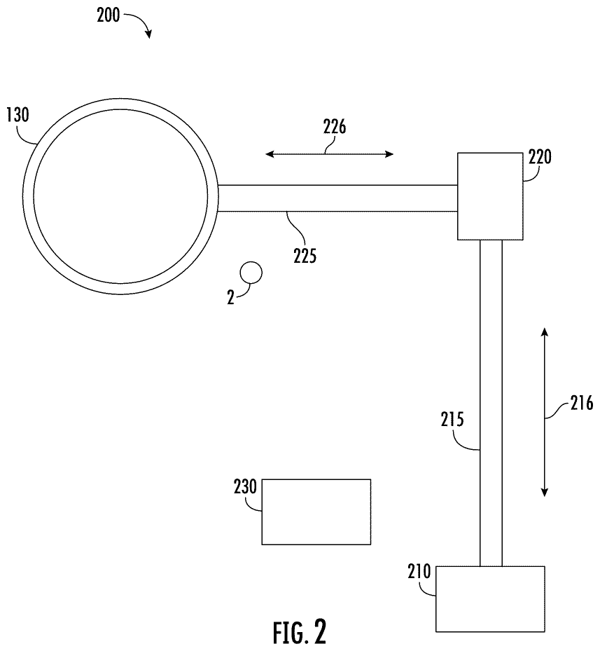

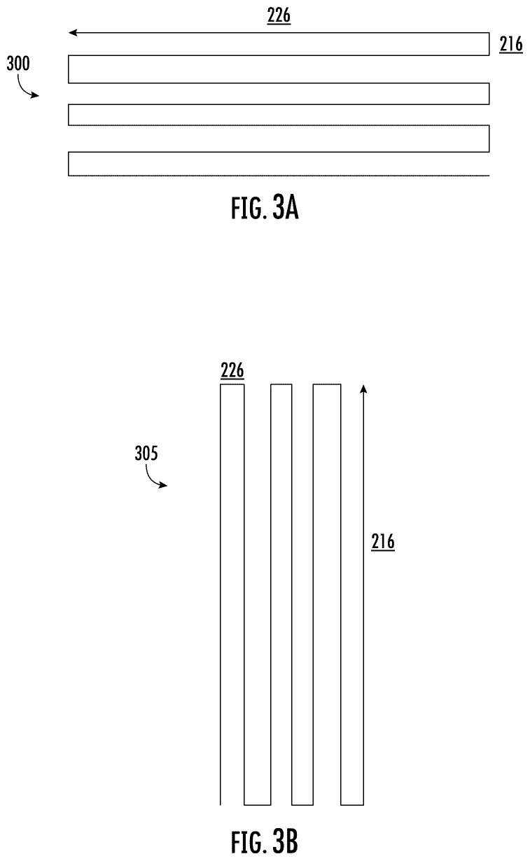

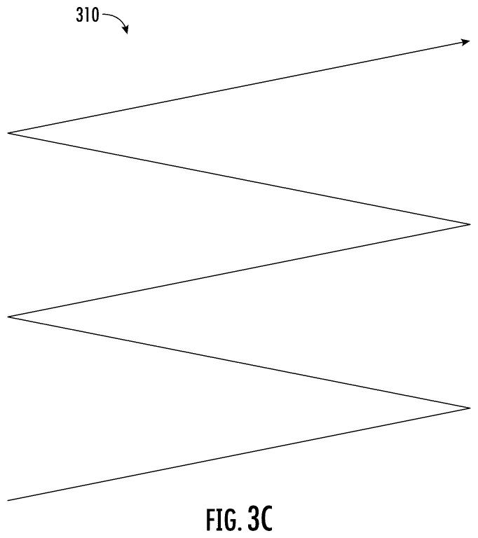

FIG. 2 shows a top view of a first embodiment of the workpiece motion system 200 and the hollow workpiece holder 130. In this embodiment, the workpiece motion system 200 comprises a first linear actuator 210 that translates a first member 215 along a first direction 216. The first member 215 may be any rigid structure, such as a metal beam or rod. In other embodiments, the first member 215 may be a section of a robotic arm or a track for a magnetic levitation stage. A second linear actuator 220 may be mounted on the first member 215. This second linear actuator 220 may be configured to translate a second member 225 in a second direction 226, perpendicular to the first direction 216. The hollow workpiece holder 130 may be mounted on the second member 225. The second member 225 may be any rigid structure, such as a metal beam, rod, section of a robotic arm or a track for a magnetic levitation stage. Note that the first direction 216 and second direction 226 may be substantially perpendicular to the direction of travel of the focused spot beam 2, wherein “substantially perpendicular” denotes within 10° of perpendicular. In some embodiments, a third actuator 230 is used to move the workpiece motion system 200 in a third direction, which is the vertical direction. Further, in some embodiments, this third actuator 230 is also capable of tilting the hollow workpiece holder 130 in the vertical direction, such that the surface of the workpiece is not perpendicular to the focused spot beam 2. For example, the range of tilt angles may be −45° to 45°, in some embodiments. In this way, the hollow workpiece holder 130 may be moved in any desired pattern. For example, in one embodiment, the second linear actuator 220 is actuated to move the hollow workpiece holder 130 in the second direction 226, while the first linear actuator 210 remains fixed. Once the workpiece moves past the focused spot beam 2, the second linear actuator 220 may stop movement. At this time, the first linear actuator 210 may move a small distance in the first direction 216. The second linear actuator 220 may then move the second member 225 so that the hollow workpiece holder 130 passes through the focused spot beam 2 in the opposite direction. This produces the motion pattern 300 shown in FIG. 3A. In some embodiments, these linear actuators may be capable of movement at up to 300 mm/sec.

In another embodiment, the first linear actuator 210 is used to move the hollow workpiece holder 130 through the focused spot beam 2 while the second linear actuator 220 is not moving. This may be used to produce the motion pattern 305 shown in FIG. 3B.

In another embodiment, both linear actuators are actuated simultaneously, which results in the diagonal motion pattern 310 shown in FIG. 3C. The slope of the diagonal lines in this diagonal motion pattern is determined based on the scan speeds associated with each linear actuator.

Furthermore, in certain embodiments, it may be advantageous to purposefully not cover the entire workpiece 10, or to move the workpiece 10 at varying speeds in one or both directions. These movements may be useful in creating a non-uniform implant pattern, which may be beneficial for workpiece strass management applications.

The controller 140 may be used to create the desired motion pattern by providing signals or commands to the two linear actuators.

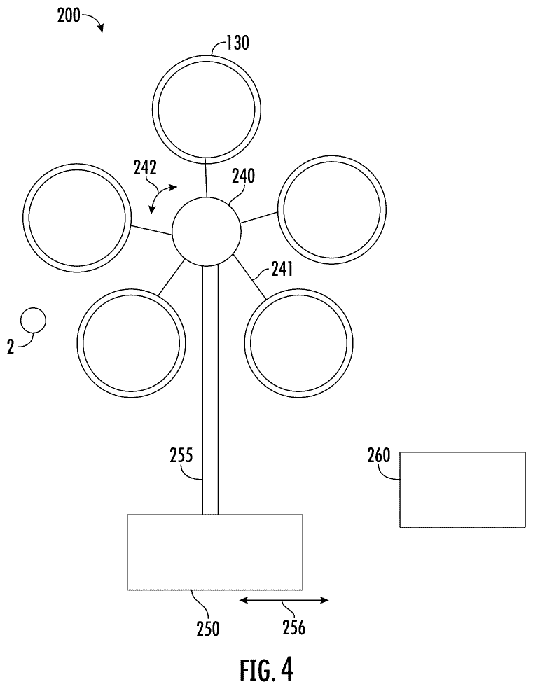

FIG. 4 shows a workpiece motion system 200 according to another embodiment. In this embodiment, there may be a plurality of hollow workpiece holders 130, each disposed at the distal end of a spoke 241. The spokes 241 may be rigid structures, such as metal or graphite rods. The proximal ends of these spokes 241 are all attached to a rotary actuator 240, which rotates in direction 242, spinning all of the hollow workpiece holders 130. The axis of rotation of the rotary actuator 240 may be parallel to the direction of travel of the focused spot beam 2. The rotary actuator 240 is attached to a member 255, which may be a rod. The member 255 may be any rigid structure, such as a metal beam or rod. This member 255 is attached to a linear actuator 250. The linear actuator 250 is able to move in direction 256. Direction 256 may be substantially perpendicular to the direction of travel of the focused spot beam 2. Thus, in this embodiment, by rotation of the hollow workpiece holders 130 using the rotary actuator 240 and simultaneous movement of the linear actuator 250, it is possible to subject multiple workpieces 10 each in a respective hollow workpiece holder 130 to the focused spot beam 2. Further, an additional actuator 260 may be used to move the workpiece motion system 200 in a second direction, which is the vertical direction. In some embodiments, this additional actuator 260 is also capable of tilting the hollow workpiece holder 130 in the vertical direction, such that the surface of the workpiece is not perpendicular to the focused spot beam 2. For example, the range of tilt angles may be −45° to 45°, in some embodiments.

Further, FIG. 1 shows the focused spot beam 2 as being upwardly oriented so as to impact the surface of the workpiece 10 that is supported by the hollow workpiece holder 130. However, it is understood that the system may be inverted, such that the ion source 100 is above the workpiece 10 and the focused spot beam 2 travels downward to impact the surface of the workpiece that is opposite that which is supported by the hollow workpiece holder 130. However, in both configurations, the focused spot beam 2 would be vertically oriented.

The systems described herein have many advantages. These ion implanter systems allow processing of either side of the workpiece 10, without contacting the useable area on the workpiece. This allows the front surface of the workpiece to be processed, and then subsequent processing of the back surface without risking damage to the nanostructures formed on the front surface. Furthermore, due to the two dimensional workpiece motion system of FIG. 2, it is possible to selectively target certain areas of the workpiece for processing, making complex implant patterns more possible. Further, the use of a blocker allows more sophisticated implant patterns. Thus, this system allows workpiece stress management with greater precision.

Further, this implanter system has few components, and lacks a mass analyzer. This simplifies the design and cost of the system while allowing it to perform the targeted actions. For example, a species such as an inert gas or a molecule comprising only one type of atom, such as nitrogen, fluorine, or oxygen, may be ionized in the ion source 100. Since there is only one type of atom, there may be limited drawbacks from eliminating the mass analysis that is performed in other systems. These ions are extracted and directed toward the workpiece 10. As described above, these ions may be focused using a beam focusing component 120 to produce a focused spot beam with a smaller diameter. The workpiece is moved relative to the spot beam using a workpiece motion system to allow all or portions of the workpiece to be implanted by the ions.

Further, the system shown in FIG. 4 allows the processing of multiple workpieces simultaneously, which may increase throughput.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An ion implanter system, comprising:
an ion source to generate a vertically oriented spot beam;
a beam focusing component to focus the vertically oriented spot beam into a focused spot beam;
a hollow workpiece holder to hold a workpiece, such that the workpiece is supported in an edge exclusion region; and
a workpiece motion system to move the hollow workpiece holder in two directions through the focused spot beam.

2. The ion implanter system of claim 1, wherein the two directions are substantially perpendicular to a direction of travel of the focused spot beam.

3. The ion implanter system of claim 1, wherein the workpiece motion system is adapted to move or tilt in a third direction, which is a vertical direction.

4. The ion implanter system of claim 1, wherein the beam focusing component comprises an electrostatic Einzel lens.

5. The ion implanter system of claim 1, wherein the beam focusing component comprises a quadrupole or octupole lens.

6. The ion implanter system of claim 1, wherein the workpiece motion system comprises two linear actuators configured to move in perpendicular directions.

7. The ion implanter system of claim 1, wherein the focused spot beam has a diameter of 5 mm or less.

8. The ion implanter system of claim 1, wherein the focused spot beam travels upward and impacts a surface of the workpiece supported by the hollow workpiece holder.

9. The ion implanter system of claim 1, further comprising a mechanism to block the focused spot beam from striking the workpiece.

10. The ion implanter system of claim 9, wherein the mechanism comprises an electrostatic or mechanical shutter.

11. The ion implanter system of claim 9, wherein the mechanism comprises pulsing a voltage applied to the ion source or to extraction optics disposed outside the ion source and proximate to an extraction aperture of the ion source.

12. An ion implanter system, comprising:
an ion source to generate a vertically oriented spot beam;
a beam focusing component to focus the vertically oriented spot beam into a focused spot beam;
a plurality of hollow workpiece holders, each to hold a respective workpiece, such that each workpiece is supported in an edge exclusion region; and
a workpiece motion system to rotate the plurality of hollow workpiece holders and to move the plurality of hollow workpiece holders through the focused spot beam.

13. The ion implanter system of claim 12, wherein the plurality of hollow workpiece holders are each mounted on a respective spoke, and the workpiece motion system comprises a rotary actuator in communication with the spokes to rotate the plurality of hollow workpiece holders.

14. The ion implanter system of claim 13, wherein an axis of rotation of the rotary actuator is parallel to a direction of travel of the focused spot beam.

15. The ion implanter system of claim 13, wherein the workpiece motion system comprises a linear actuator to move the plurality of hollow workpiece holders in a direction, wherein the direction is substantially perpendicular to a direction of travel of the focused spot beam.

16. The ion implanter system of claim 15, wherein the workpiece motion system is adapted to move or tilt in a second direction, which is a vertical direction.

17. The ion implanter system of claim 12, wherein the beam focusing component comprises an electrostatic Einzel lens, a quadrupole or octupole lens.

18. The ion implanter system of claim 12, wherein the focused spot beam has a diameter of 5 mm or less.

19. The ion implanter system of claim 12, further comprising a mechanism to block the focused spot beam from striking the workpieces.

20. The ion implanter system of claim 19, wherein the mechanism comprises an electrostatic or mechanical shutter or comprises pulsing a voltage applied to the ion source or to extraction optics disposed outside the ion source and proximate to an extraction aperture of the ion source.
